(19) United States
(12) Patent Application Publication
(10) Pub. No.: US 2013/0240232 A1
(43) Pub. Date: Sep. 19, 2013

(54) STRETCHABLE PROTECTION COVER

(71) Applicant: Mohamed Yahia Benslimane, Nordborg (DK)

(72) Inventor: Mohamed Yahia Benslimane, Nordborg (DK)

(73) Assignee: DANFOSS POLYPOWER A/S, NORDBORG (DK)

(21) Appl. No.: 13/420,708

(22) Filed: Mar. 15, 2012

(51) Int. Cl. H05K 5/00; F16J 15/10; B32B 3/30

(52) U.S. Cl. 174/50; 428/163; 277/652

(57) ABSTRACT

The present invention relates to a stretchable protection cover to protect mainly dynamic bodies, such as transducers, from being affected by particles in the environment where the dynamic bodies operate. The protection cover is formed of composites comprising a film of an elastic material having a surface with raised and depressed surface portions, and a barrier layer positioned onto this surface in a manner where the barrier layer takes form of the film surface. In one specific embodiment such composites further are used to form ring-shaped structures utilizable as O-rings.

### FIELD OF THE INVENTION

The present invention relates to a stretchable protection cover to protect mainly dynamic bodies, such as transducers, from being affected by particles, molecules, fluids etc, in the environment where the dynamic bodies operate. The protection cover is formed of composites comprising a film of an elastic material having a surface with raised and depressed surface portions, and a barrier layer positioned onto this surface in a manner where the barrier layer takes form of the film surface. In one specific embodiment such composites further are used to form ring-shaped structures utilizable as O-rings.

### BACKGROUND OF THE INVENTION

In the disclosures of e.g. WO 2008/052559 transducers, or actuators, are described of the DEAP kind, where a capacitive element is formed by having a deformable but incompressible dielectric material between two opposing electrodes. Many strategies exist in ensuring the electrodes to be flexible, such as forming corrugated surfaces of the dielectric material and when attaching the electrodes being significantly thinner than the heights for the corrugations, they thus take form of the surface being wavy, and thus being able to stretch in at least one direction, despite the electrode being formed of a stiff material.

The present invention relates to protection cover materials especially adapted to protect a dynamic body, and the manner in which they may be positioned and wrapped to protect it. They may be suitable for transducers of the kind disclosed in WO 2008/052559, but the invention is in no manner limited thereto, it could be used to protect any dynamic body operating by changing shape in general.

For DEAP transducers or actuators based on dielectric materials that may be an elastomer or another material having similar characteristics, the characteristics of these are being affected when small particles, moisture, vapours, fluids, molecules etc., diffuse into the materials, changing e.g. the dielectric constant and the break down level. In the following for simplicity these will in general be referred to a ‘particles’, this thus taking the meaning of any substances in fluid or liquid for, molecules, fluids, particles, gases, vapours etc. Therefore over time the operation characteristics of the transducers/actuators would change and become unpredictable, and it therefore would have to be changed.

The present invention solves this by introducing a simple and cheap protection cover preventing such particles from reaching the dynamic body—at least for a time—and thus prolonging its lifetime.

### SUMMARY OF THE INVENTION

This is solved by introducing a protection cover formed from at least one composite comprising:
a film made of a polymeric material and having a first surface and second surface,
a first barrier layer being deposited onto at least the first (3) surface, where the composite first surface is provided with a pattern of raised and depressed surface portions and where the barrier layer is formed according to the pattern.

Since the composites comprise a barrier material often having a significantly low elasticity that would tend to crack when stretched, therefore the film is introduced such that the barrier layer may even have a modulus of elasticity being higher than the modulus of elasticity of the film. The barrier layer takes shape from the surface pattern of the film, and this shape ensures the barrier layer may ‘follow’ the stretching of the film without cracking.

The barrier layer may be of any material suitable to form barrier against the particles etc. present in the environment where it is to operate, and may comprise plastics, clays, glass, ceramics, metal material, alloy of metals and/or just mixture of metals, and may even comprise a mixture of such materials.

The protection cover of the present invention is especially suited to form a barrier cover of dynamic bodies, being bodies able to change their size and/or shape in at least one direction, where at least one composite is wrapped at least one time around this dynamic body forming the barrier protection.

When wrapping a composite around such a dynamic body, end portions of the composites, or more especially the elastic elements, may be exposed to the environment surrounding them, thus forming ‘open doors’ for particles to enter into the inside of the films, this being highly undesirable. Therefore at least one end portion of the composites extends beyond the end of the dynamic body and at least a section of this end portion are rolled in the direction towards the dynamic body.

The protection cover with advantage may comprise a plurality of individual composites and where some may be of a first group having at least a section of their end portion rolled with a first angular direction in the direction towards the dynamic body. Alternatively or additionally other composites may form a second group having at least a section of their end portion rolled with a second angular direction in the direction towards the dynamic body. In this manner the ‘open door’ has been closed, and there are no longer any ends of the elastic materials exposed directly to the environment surrounding them.

This may even be improved by forming ‘labyrinths’ by forming first and/or second sub-groups. These are formed by rolling first and/or second groups with a first angular direction or a second angular direction in the direction towards the dynamic body in any number and permutation thereof.

In an alternative embodiment the end portion of the composites reaching free of the dynamic body is flattened, and this flattened structure of composite(s) is then rolled in the direction towards the dynamic body.

In a specific embodiment of the present invention, the surface pattern is corrugated where the raised and depressed surface portions forming waves with troughs and crests extending in essentially one common direction, each wave defining a height being a shortest distance between a crest and neighbouring troughs, such that it has a compliance direction which is at least 50 times larger than the compliance in a direction being at least substantially perpendicular to the compliance direction.

In order to design a protection cover forming a barrier protection to a wide range of particles, the protection cover may comprise a plurality of composites where at least one composite consists of materials of the barrier layer being different from at least one other of said composites, these composites are then adapted to form barriers against different particles.

The present invention also relates to transducers covered by the protection cover as given above, where the transducer is the dynamic body and is formed of similar composites as the protection cover, comprising:

a film made of a dielectric material and having a first surface and second surface, at least the first surface comprising a surface pattern of raised and depressed surface portions, and

a first electrically conductive layer being deposited onto the surface pattern, the electrically conductive layer having a corrugated shape which is formed by the surface pattern of the film.

In one specific embodiment the materials constituting the composite(s) of the transducer are the same as the materials constituting the composite(s) of the protection cover.

In even a further specific embodiment, the present protection cover is not used as such to cover a dynamic body, but is formed into an O-ring where the composite(s) are rolled into any number and permutation of first groups, second groups, first super-groups and/or second super-groups until they form a ring-shaped like structure.

### BRIEF DESCRIPTION OF THE DRAWINGS

FIG. 1 shows a composite with a surface having a pattern of raised and depressed surface portions forming one embodiment of the stretchable protection cover according to the present invention.

FIG. 2 shows a layered composites according to the present invention.

FIG. 3 shows a pattern of raised and depressed surface portions forming a second embodiment of the stretchable protection cover according to the present invention.

FIGS. 4A-C show examples of actuators forming the dynamic bodies suitable to be covered by the stretchable protection cover, according to the present invention.

FIG. 5 is an Illustration of a stretchable protection cover being wrapped around a dynamic body.

FIG. 6 is an Illustration of the stretchable protection cover wrapped around a dynamic body and flattened at the end.

FIGS. 7A-B are an illustration of the stretchable protection cover wrapped around a dynamic body, flattened at the end and rolled in the direction towards the dynamic body.

FIGS. 8A-B are an illustration of the stretchable protection cover wrapped around a dynamic body and rolled in the direction towards the dynamic body.

FIG. 9 is an illustration of the stretchable protection cover having groups and super-groups of layers of the stretchable protection rolled in the direction towards the dynamic body.

FIG. 10 is an illustration the stretchable protection cover according to the present invention being used to form a O-ring.

### DETAILED DESCRIPTION OF THE INVENTION

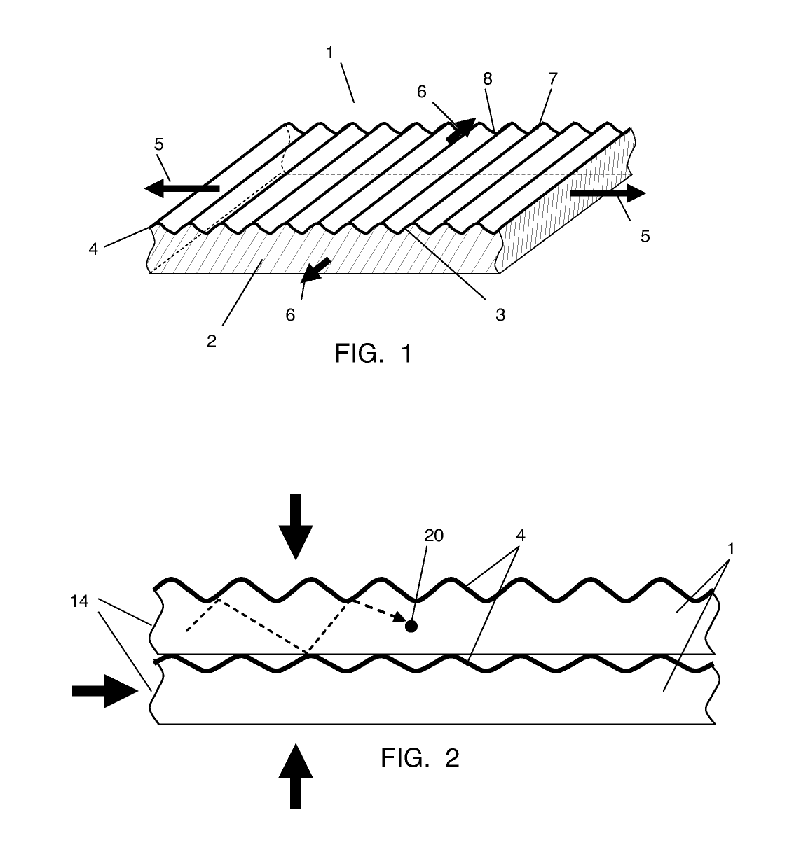

FIG. 1 illustrates a first embodiment of the protection cover of the present invention, where a pattern of raised and depressed surface portions in at least a first surface of a film of a deformable/elastic material, such as a polymer or more specifically an elastomer, in the following in general referred to as a elastic material.

On the first surface a material of a substantially stiff material is positioned, e.g. by a deposition technique of any kind, as also discussed in relation to the electrically conductive layer of the WO 2008/052559. In the following this substantially stiff material will be referred to as a barrier layer, where the barrier layer may be of any material suitable to form a barrier to such particles (fluids, molecules, gasses etc), such as plastics, clays, metal material, alloy of metals or just mixture of metals optionally including other materials too. The barrier layer may also be a mixture of such materials.

Since the barrier layer is of a substantially stiff material, then this may easily crack the barrier layer upon stretching, thus reducing its barrier efficiency. To overcome this the protection cover is formed as a composite (1) adapted to form part of a compliant structure capable of withstanding large strains. The composite (1) comprises a film (2) made of an elastic material having a surface (3) provided with a pattern of raised (7) and depressed (8) surface portions, thereby forming a designed corrugated profile of the surface (3). A barrier layer (4) has been applied to the surface (3), the barrier material being deposited so that the shape of the barrier layer (4) is formed according to the pattern of raised (7) and depressed (8) surface portion. This is due to its thickness being significantly smaller than the heights from the depressed (8) to the raised (7) surface portions.

The elastic material may be a polymer, elastomer or another material having similar characteristics. Due to the pattern of raised and depressed surface portions, the barrier layer (4) may substantially even out as the film (2) expands, and recover its original shape as the film (2) contracts along the direction defined by arrows (5) without causing damage to the barrier layer (4), this direction thereby defining a direction of compliance. Accordingly, the composite (1) is adapted to form part of a compliant structure capable of withstanding large strains. Due to the stiffness of the barrier layer (4) this composite (1) is much more compliant in the direction (5) than in the orthogonal direction (6).

Together such a laminated composite structure (1) forms a flexible (in the present example mainly flexible in one direction) barrier for the diffusion of particles through the composite (1). The elastic element (2), being in it self stretchable, forms the wavy structure of the barrier layer (4), and the barrier layer (4) forms a barrier against the diffusion of particles through the composite (1).

When layering a plurality of such composites (1) as e.g. in the manner illustrated in FIG. 2, the resulting barrier is improved due to the increased number of layers, but also because of the parallel barrier layers (4) gives so to speak a ‘tunnel’ where particles (20) may be trapped for a while, and where they may just as well end up leaving the laminated barrier without reaching the object it covers. That the barrier layers (2) are parallel in this context is to be understood in the sense they are parallel within the general tolerances of the manufacturing techniques seen in the large picture disregarding the corrugations, whereas seen in the more local picture within sizes of the corrugations the barrier layers (2) will usually be highly non-parallel, since the present invention does not as such require the corrugations of neighbouring composites (1) to be aligned.

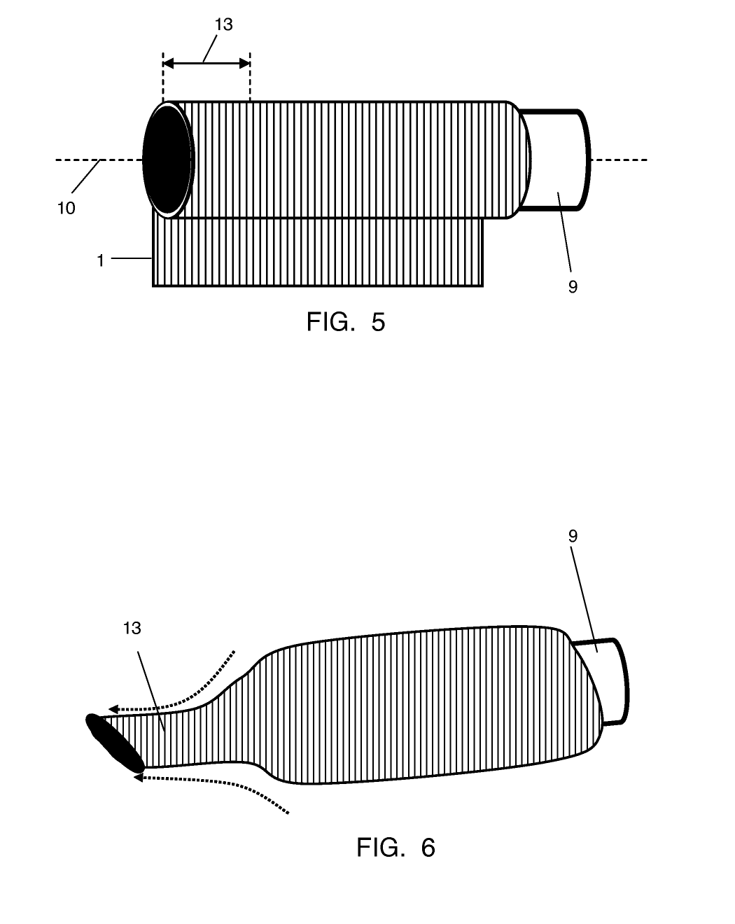

Such composites (1) as illustrated in FIG. 1 where the corrugations run in parallel are especially suited for dynamic bodies (9—FIG. 5) only changing shape in one direction.

When forming by a plurality of such composites (1), one may add layers with composites (1) formed of different materials of the elastic elements (2) and/or barrier layers (4). This for example could be used to design the protection cover such that each individual layer of the individual composites (1) is adapted to form barrier against specific particles, so that a protection cover may be formed that is designed to protect against a wide range of particles.

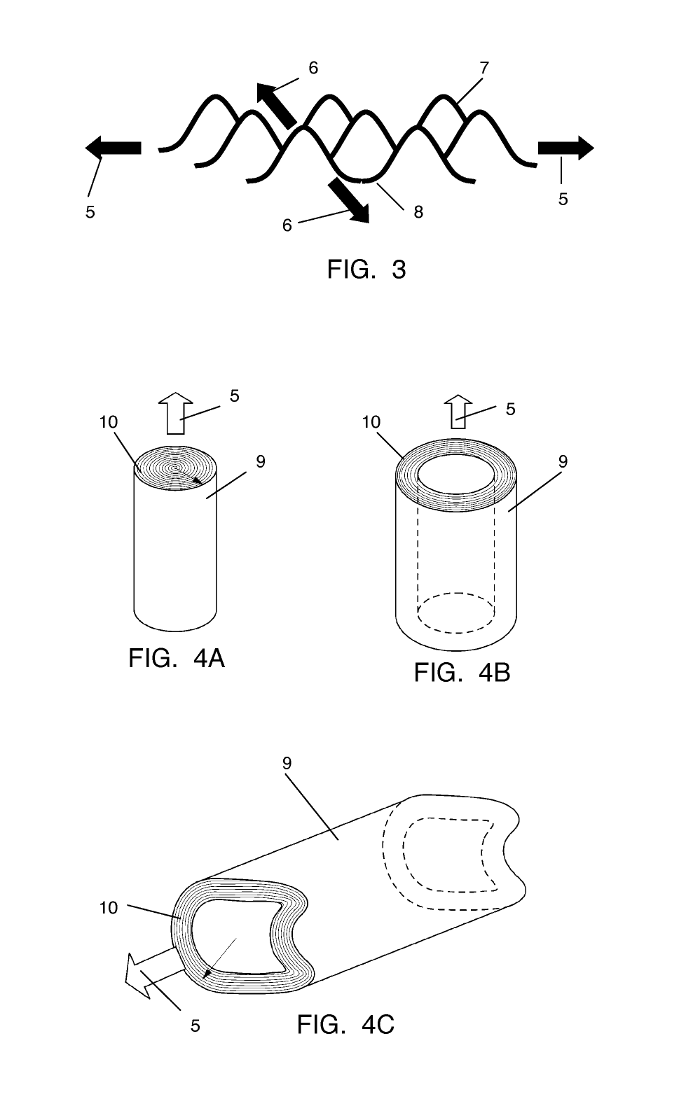

FIG. 3 illustrates an alternative surface pattern of raised and depressed surface portions, where the raised (7) portions rather are shaped somewhat like ‘mountains’ the depressions (8) being ‘valleys’ between the raised portions. Such a surface pattern would be stretchable (or flexible or compliant) in any direction (5) and (6) and could therefore be applied to any dynamic body (9—FIG. 5).

Any imaginable surface pattern alternative surface pattern of raised (7) and depressed (8) surface portions would also apply to the present invention. The exact design would typically depend on the possibilities according to manufacturing tools and the need for relative compliances or flexibilities in different directions.

FIG. 4A to FIG. 4C illustrate examples of a dynamic body (9) where the composites (1) of the present invention with advantage could be used as barrier covers. The dynamic bodies (9) illustrated are EAP (or DEAP) transducers formed in similar manners as the composites (1) of the present invention and are also further described in e.g. WO 2008/052559, where one or more of such composites (1) comprising a corrugated surface carrying electrodes are wrapped to form a transducer able to elongate (or widen, this being a matter of the orientation of the corrugations) when a voltage is applied to the electrodes. They may be with (FIGS. 4B and 4C) or without (FIG. 4A) a hollow core, and may be of a circular (FIGS. 4A and 4B) or non-circular (FIG. 4C) cross sectional shapes.

Since such transducers may be formed of composites like the ones of the present invention they could be manufactured identically by the same tools, optionally even from the same materials, the present composites (1) simply being layers of transducer-composites not being connected to any power-supply.

FIG. 5 illustrates a protection cover where a plurality of layers of protection cover are wrapped around a dynamic body (9) (a transducer as illustrated in FIGS. 4A-C or any other kind of dynamic body), either a as a plurality of individual composites (1) arranged in a laminated manner, or one composite (1) being wrapped a plurality of times, or a combination thereof. In the illustration the composite(s) (1) is wrapped at least one time around the dynamic body (9) in a manner where it is wrapped around a line (10) parallel to a first direction.

The composite(s) (1), or some of the composites (1), may be positioned on the dynamic body (9) such that an end portion (13) of the composites (1) extends beyond the end of the dynamic body (9), thus forming a tubular section of wrapped protection cover with a hollow inside.

In the figure the composite(s) (1) is/are only seen covering part of the dynamic body (9) and only extending free (13) from one of its ends, but this is purely for illustration, usually the whole of the dynamic body (9) will be covered and the composite(s) (1) extending free (13) from both of its ends.

When forming such a rolled or wrapped protection cover, a problem arises in relation to the end surfaces (14)—see also FIG. 2—of the composites (1). The elastic material of film (2) may not form any barrier to particles in it self, it may even have high diffusion to such particles. Therefore, if its end surfaces (14) are exposed to the environment surrounding them, this will form ‘open doors’ for the penetration of particles into the protection cover.

Referring again to FIG. 2, here the black arrows illustrate that particles in the sense of the present text may enter into the composites (1) from all sides, it may come from the outside, the inside, or from the end portions (14) exposed to the environments surrounding them. Of these the most critical are the end portions (14). For those coming from the ‘outside’, they will encounter often a plural of barrier layers (4) before reaching to the dynamic body (9) within the protection cover. However for those entering from the end portions (14) or even from the inside of the protection cover, the cover may actually rather form a ‘highway’ through the elastic material to the dynamic body (9), are must therefore be close.

All of this is not very desirable. Therefore the present invention presents solutions of how to ‘close the door’. This is done by rolling ends of the composites (1) as shall be described in the following.

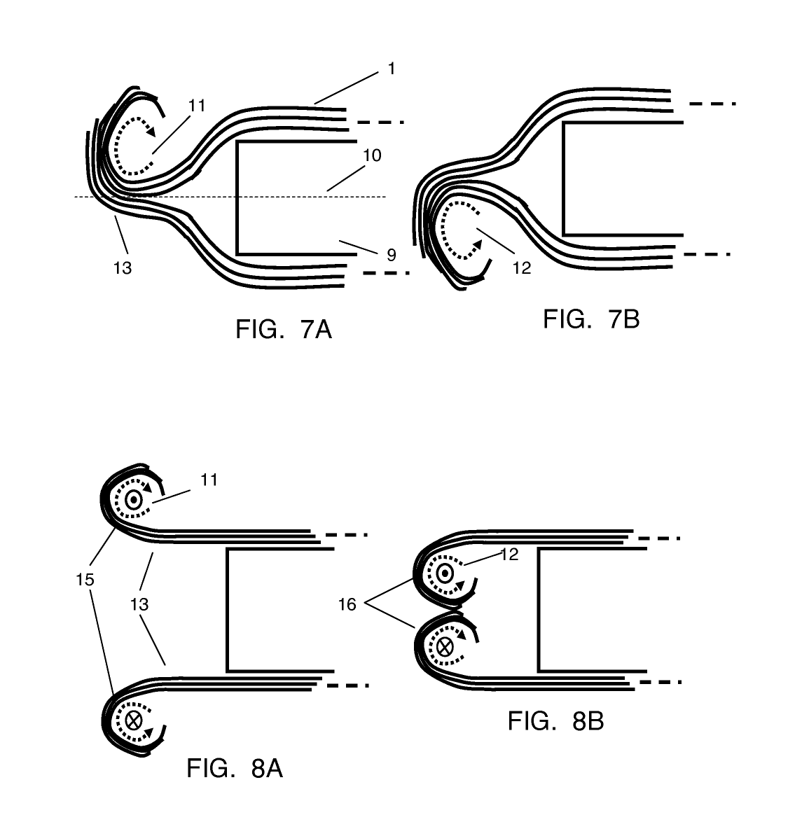

In FIG. 6 this end portion (13) has been ‘collapsed’ so that at least the end (14) of the end portion (13) is flat and non-hollow, and at least the end part of this end portion (13) is then rolled in the direction of the first line (10) towards the dynamic body (9) in a first angular direction (11), as illustrated in FIG. 7A. As in any of the figures, the illustration in FIG. 7A is highly illustrative and does not reflect the actual sizes or relative sizes of the parts, nor showing the surface pattern of raised (7) or depressed (8) portions. In FIG. 7A and some of the following figures, the composites (1) are just represented by a line, and though in the illustration there may seem to appear ‘gaps’ between these line, then these ‘gaps’ are only to be able to distinguish the individual layers, or composites (1), of the protection cover.

FIG. 7B illustrates the flattened section of the end portion (13) rolled in the direction of the first line (10) towards the dynamic body (9) in a second angular direction (12), the second angular direction (12) being counter-wise to the first angular direction (11). Rolling ‘in the direction of the first line (10) means rolling around an axis parallel to the first line (10).

FIG. 8A shows the same system to that of FIG. 5, but where the end portion (13) has not been collapsed, but instead the tubular shaped composite(s) (1) is rolled in a first angular direction in the direction of the first line (10) towards the dynamic body (9) such that at least a section of this end portion (13) forms a rolled structure encircling the line (10), either outside the remaining part of the protection cover when rolled in the first angular direction (11) as seen in FIG. 8A, or inside the remaining part of the protection cover when rolled in the second angular direction (12) as seen in FIG. 8B. This operation is possible due to the flexibility/stretchability of the composites (1). In FIG. 8A rolling in the first angular direction (11) gives a rolled portion being ‘outside’ the protection cover, and the second angular direction (12) in FIG. 8B gives a rolled portion being ‘inside’ the protection cover, but which is not important to the present invention, the matter is they are rolled at counter angular directions to each other.

In the present context it is to be understood the term ‘encircling’ is not to be limited to only circular structures, but the ‘encircling’ shape usually will be reflected in the cross sectional shape, or the profile, of the wound composite(s) (1) forming the protection cover, where this again usually will be reflected in the shape, or profile, of the dynamic body (9).

In the same manner ‘tubular’ is not limited to a rounded shape, e.g. circular or oval, but relates to ‘tubes’ of any cross sectional shape or profile.

The end portions (13) exposed to the environment surrounding them extending beyond the end of the dynamic body (9) may be rolled fully or partly and may be rolled tightly or loosely in the manners as described above.

When the protection cover is formed from a plurality of individual neighbouring composites (1), their end portions (13) may be rolled differently, some of the composites (1) rolled in the first angular direction (11), as seen in FIG. 8A, this could be called a first group (15), and others rolled in the second angular direction (12), as seen in FIG. 8B, this could be called a second group (16).

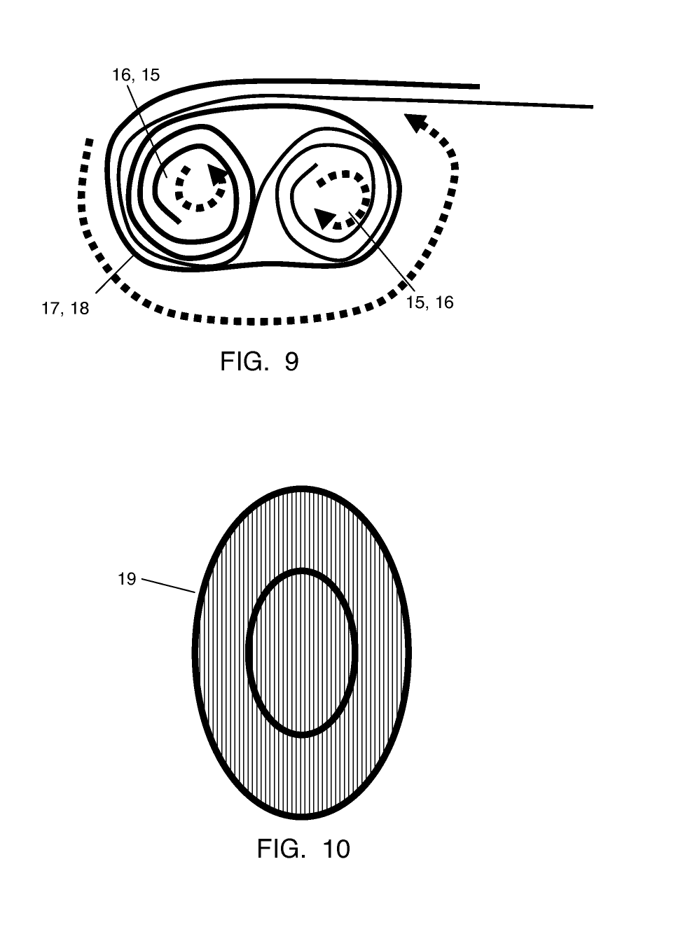

As illustrated in FIG. 9, any number of such first groups (15) and/or second groups (16) may then further be rolled into a first (17) or second (18) kind super-group, this thus being a group comprising other groups. Such super-groups (17) and (18) may comprise any number and permutation of first (15) and second (16) kind of groups and other super-groups (17) and (18). In this manner any single composite (1) may form part of several groups or super-groups, as also illustrated in FIGS. 8A and 8B.

In one specific embodiment the protection cover is not formed to enclose a dynamic body (9), but instead the end portion (13) is regarded to be the whole extension of the wound or rolled composite(s) (1), these are then rolled in any manner as described above over the whole extension of the composite(s) (1), such they form a ring-shaped (19) like structure. The combined rolling may include any permutation and number of first groups (15), second groups (16), first super-groups (17) and/or second super-groups (18).

Such ring-shaped structures (19), FIG. 10, may then with advantage be used e.g. as highly gas tight O-rings due to their highly flexible/stretchable structure. Where normal rubber O-rings do not really form a barrier to particles, they will more or less just let them pass, then the present ring-shaped structures (19) will form a ‘labyrinth’ of barrier layers (4) and film (2) is made of an elastic material.

While the present invention has been illustrated and described with respect to a particular embodiment thereof, it should be appreciated by those of ordinary skill in the art that various modifications to this invention may be made without departing from the spirit and scope of the present.

What is claimed is:

1. A protection cover formed from at least one composite comprising:
a film made of a polymeric material and having a first surface and second surface, and
a first barrier layer being deposited onto at least the first surface where the composite first surface is provided with a pattern of raised and depressed surface portions and where the barrier layer is formed according to the pattern.

2. The protection cover according to claim 1, wherein the barrier layer has a modulus of elasticity being higher than the modulus of elasticity of the film.

3. The protection cover according to claim 2, wherein the barrier layer comprises plastics, clays, glass, ceramics, metal material, alloy of metals and/or just mixture of metals.

4. The protection cover according to claim 3, wherein the barrier layer comprises a mixture of said materials.

5. The protection cover according to claim 1, wherein at least one composite is wrapped at least one time around a dynamic body.

6. The protection cover according to claim 5, wherein the at least one end portion of the composites extends beyond the end of the dynamic body and where at least a section of end portion is rolled in the direction of a first line towards the dynamic body.

7. The protection cover according to claim 6, comprising a plurality of individual composites and wherein some form a first group having at least a section of their end portion rolled with a first angular direction in the direction of a first line towards the dynamic body.

8. The protection cover according to claim 7, wherein other composites form a second group having at least a section of their end portion rolled with a second angular direction in the direction of a first line towards the dynamic body.

9. The protection cover according to claim 8, wherein first and/or second super-groups are formed by rolling first and/or second groups with a first angular direction or a second angular direction in the direction of a first line towards the dynamic body in any number and permutation thereof.

10. The protection cover according to claim 6, wherein the end portion of the composites extends beyond the end of the dynamic body is flattened out, and this flattened structure of composite(s) is then rolled in the direction of a first line towards the dynamic body.

11. The protection cover according to claim 1, wherein the surface pattern is corrugated where the raised and depressed surface portions forming waves with troughs and crests extending in essentially one common direction, each wave defining a height being a shortest distance between a crest and neighbouring troughs, such that it has a compliance direction which is at least 50 times larger than the compliance in a direction being at least substantially perpendicular to the compliance direction.

12. The protection cover according to claim 1, wherein the protection cover comprises a plurality of composites, and where at least one composite consists of materials of the barrier layer being different from at least one other of said composites.

13. A transducer covered by the protection cover according to claim 2, wherein the transducer is the dynamic body and is formed of similar composites as the protection cover, comprising:
a film made of a dielectric material and having a first surface and second surface, at least the first surface comprising a surface pattern of raised and depressed surface portions, and
a first electrically conductive layer being deposited onto the surface pattern, the electrically conductive layer having a corrugated shape which is formed by the surface pattern of the film.

14. The transducer according to claim 13, wherein the materials constituting the composite(s) of the transducer are the same as the materials constituting the composite(s) of the protection cover.

15. An O-ring formed from composite(s) according to claim 1, and wherein the composite(s) are rolled into any number and permutation of first groups, second groups, first super-groups and/or second super-groups until they form a ring-shaped like structure.
